(19) United States
(12) Patent Application Publication
(10) Pub. No.: US 2018/0114870 A1
(43) Pub. Date: Apr. 26, 2018

(54) OPTICAL PACKAGE STRUCTURE

(71) Applicant: NANYA TECHNOLOGY CORPORATION, Taoyuan City (TW)

(72) Inventor: Po-Chun LIN, Changhua County (TW)

(21) Appl. No.: 15/331,908

(22) Filed: Oct. 23, 2016

(51) Int. Cl. H01L 31/0232; H01L 25/16; H01L 31/02; H01L 23/00

(52) U.S. Cl. CPC H01L 31/02325; H01L 25/167; H04B 10/27; H01L 24/16; H01L 2224/16145; H01L 31/02005

(57) ABSTRACT

A package structure includes a substrate, an interconnection unit, and an optical unit. The substrate has a surface. The interconnection unit is disposed on the substrate and includes a reflective bump, in which reflective bump is disposed on the surface of the substrate and has an opening therein. The optical unit is joined with the surface of the substrate and configured to receive a light beam from the interconnection unit, in which a vertical projection of the optical unit on the substrate is present within a vertical projection of the opening of the reflective bump on the substrate.

### BACKGROUND

### Technical Field

The present disclosure relates to a package structure.

### Description of Related Art

With a development of the data processing, the data transmission speed of a bus has gradually fallen behind the data calculation speed of a central processing unit (CPU). Therefore, an optical signal transmission has been implemented for speeding the data transmission speed. In addition, the optical signal transmission has substantially higher bandwidth in comparison to electrical signal transmission. In an optical transmission system, electrical signals representing binary data are converted into optical signals, and the optical signals are transmitted through an optical channel to an optical receiver and converted back to electrical signals. The condition of receiving the optical signal by the optical receiver may affect the transmission efficiency of the data transmission.

### SUMMARY

An aspect of the present disclosure provides a package structure including an optical unit and an interconnection unit, in which the interconnection unit includes a reflective bump. With the reflective bump, a light beam which does not be propagated toward the optical unit at the start can reach the optical unit through being reflected from the reflective bump. Therefore, the light beam serving as an optical signal can be prevented from leaking out of the package structure, and thus the transmission efficiency of the package structure is enhanced.

An aspect of the present disclosure provides a package structure including a substrate, an interconnection unit, and an optical unit. The substrate has a surface. The interconnection unit is disposed on the substrate and includes a reflective bump, in which reflective bump is disposed on the surface of the substrate and has an opening therein. The optical unit is joined with the surface of the substrate and configured to receive a light beam from the interconnection unit, in which a vertical projection of the optical unit on the substrate is present within a vertical projection of the opening of the reflective bump on the substrate.

An aspect of the present disclosure provides a package structure including a first substrate, a second substrate, an interconnection unit, a first optical unit, and a second optical unit. The first substrate has a first surface. The second substrate is disposed on the first substrate and has a second surface, in which the first surface and the second surface face toward each other. The interconnection unit is disposed between the first substrate and the second substrate, in which the interconnection unit includes a reflective bump disposed between the first surface and the second surface and has a tunnel therein, and the tunnel extends from the first surface to the second surface. The first optical unit is joined with the first surface of the first substrate. The second optical unit is joined with the second surface of the second substrate. One of the first optical unit and the second optical unit is configured to emit a light beam toward the tunnel and another one of the first optical unit and the second optical unit is configured to receive the light beam from the tunnel.

### BRIEF DESCRIPTION OF THE DRAWINGS

FIG. 1A is a perspective view of a package structure according to a first embodiment of the present disclosure;

FIG. 1B is a cross-sectional view of the package structure taken along the line 1B-1B illustrated in FIG. 1A;

FIG. 2A is a perspective view of a package structure according to a second embodiment of the present disclosure;

FIG. 2B is a cross-sectional view of the package structure illustrated in FIG. 2A with the same cross-section as FIG. 1B;

FIG. 3 is a perspective view of a package structure with the same cross-section as FIG. 1B according to a third embodiment of the present disclosure;

FIG. 4 is a perspective view of a package structure with the same cross-section as FIG. 1B according to a fourth embodiment of the present disclosure;

FIG. 5 is a perspective view of a package structure with the same cross-section as FIG. 1B according to a fifth embodiment of the present disclosure; and

FIG. 6 is a perspective view of a package structure with the same cross-section as FIG. 1B according to a sixth embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

It will be understood that, although the terms first, second, third etc. may be used herein to describe various elements, components, regions, layers and/or sections, these elements, components, regions, layers and/or sections should not be limited by these terms.

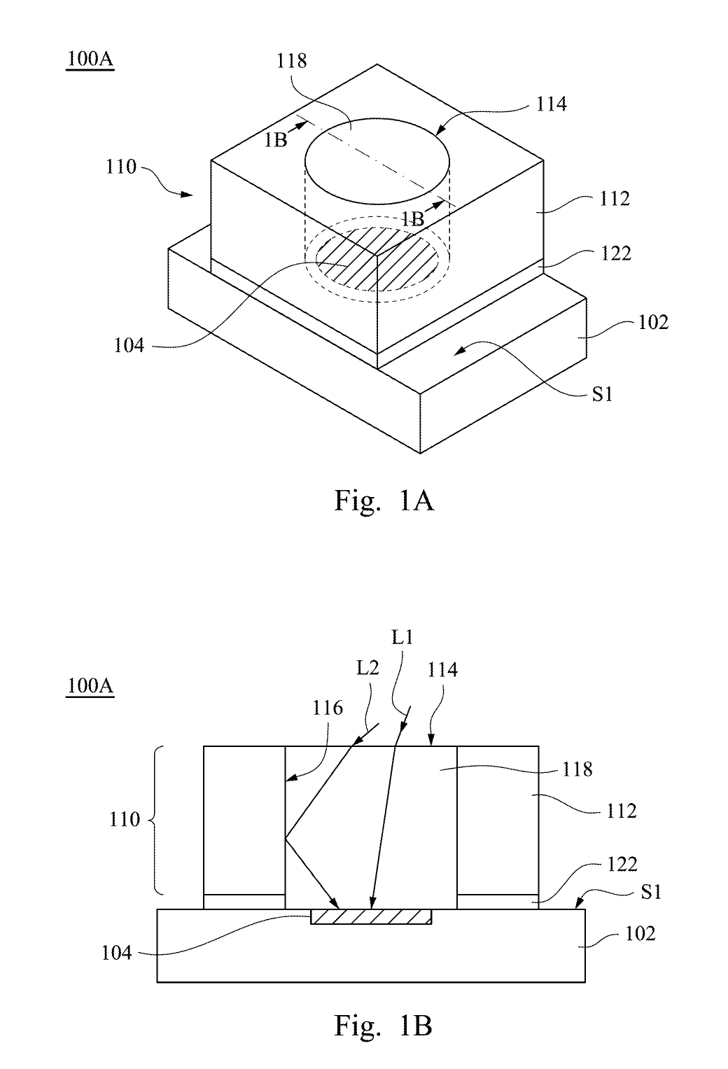

FIG. 1A is a perspective view of a package structure 100A according to a first embodiment of the present disclosure, and FIG. 1B is a cross-sectional view of the package structure 100A taken along the line 1B-1B illustrated in FIG. 1A. The package structure 100A can be configured to receive an optical signal, such as a light beam, and then the optical signal may travel in the package structure 100A or may be transferred into an electrical signal. The package structure 100A includes a first substrate 102, a first optical unit 104, and an interconnection unit 110.

The first substrate 102 has a first surface S1, in which the first optical unit 104 is joined with the first surface S1 of the first substrate 102. The first optical unit 104 may be a light-inlet surface of a fiber extending into the first substrate 102 or an optoelectronic transfer configured to transfer an optical signal into an electrical signal.

The interconnection unit 110 is disposed on the first substrate 102. The package structure 100A can be connected with an external device through the interconnection unit 110. For example, the package structure 100A can be bonded with an interposer having an optical emitter through the interconnection unit 110. The interconnection unit 110 includes a reflective bump 112, a first dielectric layer 118, and a first pad 122, in which the reflective bump 112, a first dielectric layer 118, and a first pad 122 are disposed on the first surface S1 of the first substrate 102. The first pad 122 is present between the first substrate 102 and the reflective bump 112, and the first optical unit 104 is present between the first substrate 102 and the first dielectric layer 118. In addition, in other embodiments, interconnection unit 110 further includes an insulator layer (not illustrated) surrounding the first pad 122.

The reflective bump 112 disposed on the first pad 122 can be in contact with the first pad 122. The reflective bump 112 has an opening 114 therein, in which the location of the opening 114 can be defined by the first pad 122, but may not be limited thereto. For example, since the reflective bump 112 is formed in a standing manner on the first pad 122, the first pad 122 may determine the location of reflective bump 112 during the manufacturing process. In this regard, the first pad 122 surrounds the first optical unit 104 and a portion of the opening 114 of the reflective bump 112. The vertical projection of the first optical unit 104 on the first substrate 102 may be present within a vertical projection of the opening 114 of the reflective bump 112 on the first substrate 102.

The reflective bump 112 can be a hollow cylinder, and a vertical projection of the reflective bump 112 on the first substrate 102 is a closed-loop annularity, but may not be limited thereto. In addition, the reflective bump 112 can be made of metal, such as tin (Sn), and the reflective bump 112 and the first pad 122 can be made of the same material or different materials. In some embodiments in which the reflective bump 112 is made of metal, since the metal may be capable of self-aligning in a joint process during the manufacturing process of the package structure 100A, the yield rate of the package structure 100A can be improved.

The first dielectric layer 118 is disposed in the opening 114 of the reflective bump 112. The reflective bump 112 has an inner sidewall 116 facing toward the opening 114, and the first dielectric layer 118 can be in contact with the inner sidewall 116 and the first optical unit 104, but is not limited thereto. The first dielectric layer 118 can be a cylinder corresponding to the shape of the opening 114. In addition, the first dielectric layer 118 can be made of a material that is transparent to light in some wavelengths, such as silicon dioxide. With the first dielectric layer 118, the structural strength of the interconnection unit 110 is enhanced. Furthermore, the first dielectric layer 118 can serve as a protective layer for the first optical unit 104 during the manufacturing process of the package structure 100A.

Under this configuration, once an optical signal is inputted into the package structure 100A from a interposer (not illustrated) connected with the interconnection unit 110, the package structure 100A can receive the optical signal by the first optical unit 104 through the interconnection unit 110, and the optical signal can be prevented from leaking out of the package structure 100A by the interconnection unit 110. For example, as shown in FIG. 1B, an optical signal is labeled as light beams L1 and L2.

An exemplary optical path of the light beams L1 and L2 is illustrated in FIG. 1B. The light beams L1 and L2 are propagated from the upper side of the package structure 100A, in which the light beam L1 travels toward the first optical unit 104 and the light beam L2 travels toward the inner sidewall 116 of the reflective bump 112 at the start. The light beam L1 can be directly received by the first optical unit 104 through the first dielectric layer 114. The light beam L2 can be reflected by the reflective bump 112, and then the light beam L2 reflected from the inner sidewall 116 of the reflective bump 112 travels toward the first optical unit 104 and thus is received by the first optical unit 104.

With the reflective bump 112, the light beam L2 which does not be propagated toward the first optical unit 104 at the start can reach the first optical unit 104 through being reflected from the inner sidewall 116 of the reflective bump 112. Therefore, the optical signal can be prevented from leaking out of the package structure 100A, and thus the transmission efficiency of the package structure 100A is enhanced.

In the following embodiments, descriptions are provided with respect to variations of the arrangement of the package structure, and aspects of the below embodiments that are the same as the first embodiment are not described again.

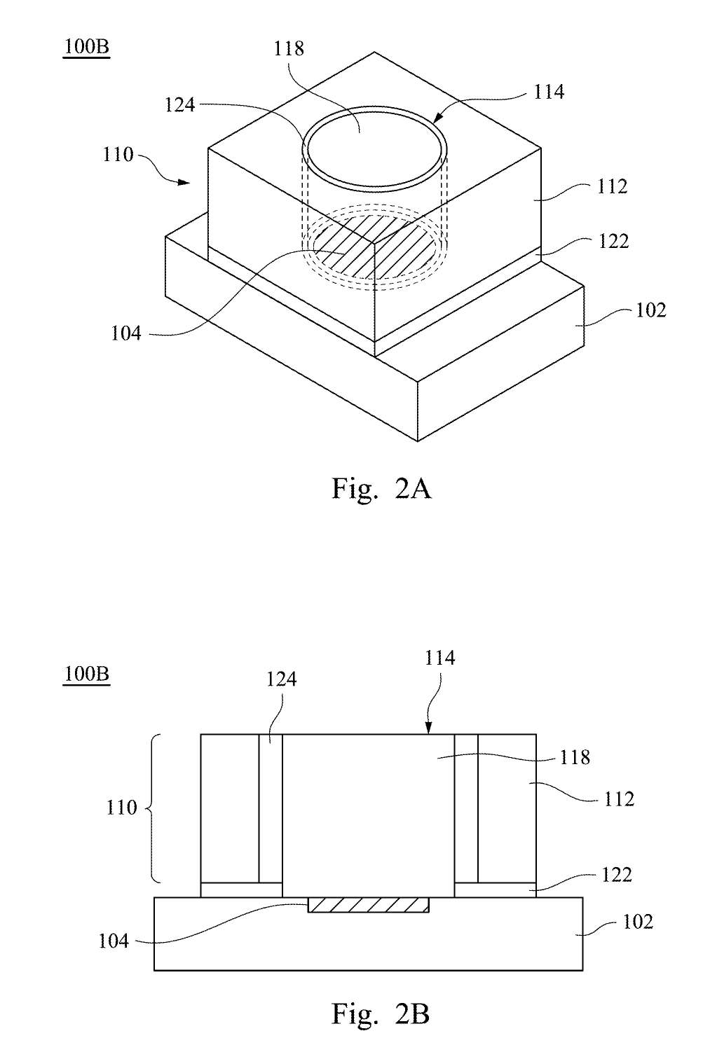

FIG. 2A is a perspective view of a package structure 100B according to a second embodiment of the present disclosure, and FIG. 2B is a cross-sectional view of the package structure 100B illustrated in FIG. 2A with the same cross-section as FIG. 1B. The difference between the present embodiment and the first embodiment is that the interconnection unit 110 of the present embodiment further includes a metal layer 124 disposed in the opening 114 of the reflective bump 112 and between the first dielectric layer 118 and the reflective bump 112.

As shown in FIGS. 2A and 2B, a vertical projection of the metal layer 124 on the first substrate 102 is annular, and the vertical projection of the metal layer 124 on the first substrate 102 is out of the vertical projection of the first optical unit 104 on the first substrate 102, such that the metal layer 124 may not block the light beam traveling from the upper side of the package structure 100A toward the first optical unit 104. In addition, the opening 114 of the reflective bump 112 can be filled with a combination of the first dielectric layer 118 and the metal layer 124. The metal layer 124 can be made of a material having high reflectivity, such as cooper (Cu). In addition, at least two of the reflective bump 112, the first pad 122, and the metal layer 124 can be made of the same material, but may not be limited thereto. With the high reflectivity of the metal layer 124, the transmission of the optical signal can be more accurate, such that the transmission efficiency of the package structure 100B is enhanced further. Furthermore, in other embodiments, the first dielectric layer 118 can be omitted, and an air gap is present in the opening 114 and is surrounded by the metal layer 124.

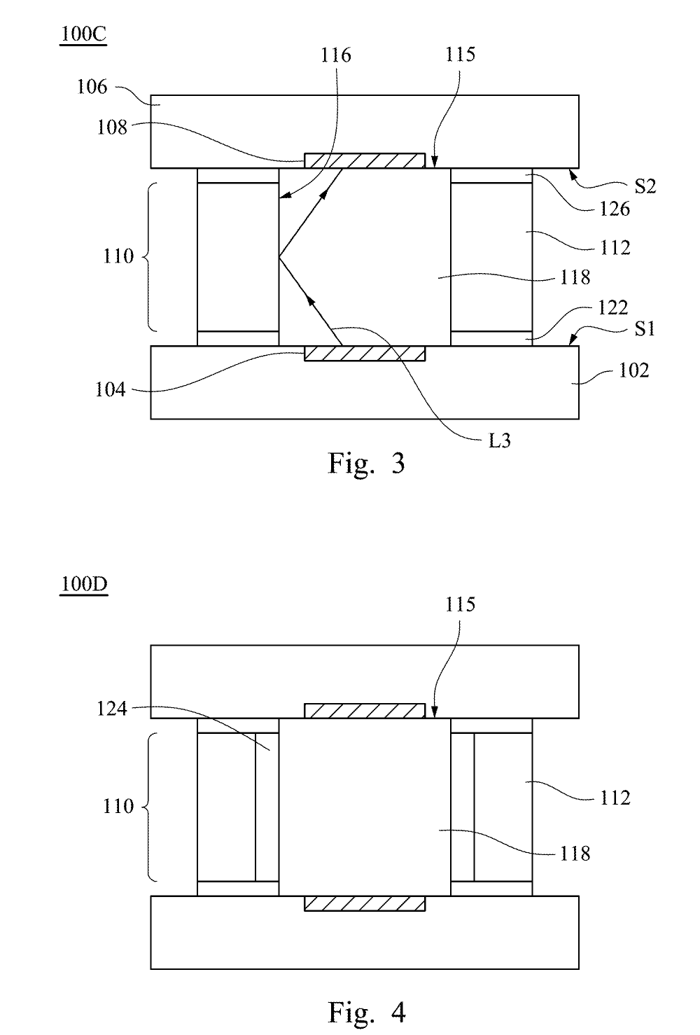

FIG. 3 is a perspective view of a package structure 100C with the same cross-section as FIG. 1B according to a third embodiment of the present disclosure. The different between the present embodiment and the first embodiment is that the package structure 100B further includes a second substrate 106 and a second optical unit 108. Furthermore, the transmission of the optical signal in the package structure 100C of the present embodiments can be referred to as an internal transmission (i.e. emitting and receiving in the package structure 100C), and the transmission of the optical signal in the package structure 100A of the first embodiments can be referred to as an external transmission (i.e. emitting from an external component and receiving in the package structure 100A).

As shown in FIG. 3, the second substrate 106 is disposed on the first substrate 102, and the interconnection unit 110 is deposed between the first substrate 102 and the second substrate 106. The second substrate 106 has a second surface S2, in which the first surface S1 of the first substrate 102 and the second surface S2 of the second substrate 106 face toward each other.

The interconnection unit 110 further includes a second pad 126. The second pad 126 is disposed between the second substrate 106 and the interconnection unit 110, in which the interconnection unit 110 is connected with the second surface S2 of the second substrate 106 through the second pad 126. In addition, the interconnection unit 110 is in contact with the first surface S1 of the first substrate 102 and the second surface S2 of the second substrate 106.

The reflective bump 112 of the interconnection unit 110 has a tunnel 115 therein to replace the opening 114 (see FIG. 1B). The tunnel 115 of the reflective bump 112 extends from the first surface S1 of the first substrate 102 to the second surface S2 of the second substrate 106, in which the first dielectric layer 118 is in the tunnel 115 of the reflective bump 112 and between the first substrate 102 and the second substrate 104. Similarly to the first embodiment, the vertical projection of the reflective bump 112 of the interconnection unit 110 on the first substrate 102 or the second substrate 104 is closed-loop. Furthermore, since the interconnection unit 110 is in contact with the first surface S1 and the second surface S2, two ends of the tunnel 115 of the reflective bump 112 are covered with the first substrate 102 and the second substrate 104 such that the tunnel 115 may become a closed chamber in the reflective bump 112. In addition, the two ends of the tunnel 115 can be respectively surrounded by the first pad 122 and the second pad 126. In some embodiments in which the tunnel 115 becomes the closed chamber, the tunnel 115 can be filled with the first dielectric layer 118, and thus the medium in the tunnel 118 is homogeneous.

The second optical unit 108 is joined with the second surface S2 of the second substrate 106. In the present embodiments, the first optical unit 104 is configured to emit light beams into the tunnel 115, and the second optical unit 108 is configured to receive light beams from the tunnel 115. For example, the first optical unit 104 and the second optical unit 108 may be optoelectronic transfers, in which the first optical unit 104 is configured to receive an electrical signal from an external component (not illustrated) and transfer the electrical signal into an optical signal, and the second optical unit 108 is configured to receive an optical signal and transfer the optical signal into an electrical signal. In other embodiments, at least one of the first optical unit 104 and the second optical unit 108 may be a fiber extending into the first substrate 102 or the second substrate 106. In addition, a vertical projection of the first optical unit 104 on the first substrate 102 is present within the vertical projection of the tunnel 115 on the first substrate 102, and a vertical projection of the second optical unit 108 on the second substrate 106 is present within a vertical projection of the tunnel 115 on the second substrate 106.

Under this configuration, once the first optical unit 104 emits an optical signal into the tunnel 115 and the first dielectric layer 118, the optical signal can be prevented from leaking out of the package structure 100C by the interconnection unit 110. For example, once the first optical unit 104 emits a light beam L3 which does not be propagated toward the second optical unit 108 at the start, the light beam L3 can reach the second optical unit through being reflected from the inner sidewall 116 of the reflective bump 112. Therefore, the optical signal can be prevented from leaking out of the package structure 100C, and thus the transmission efficiency of the package structure 100C is enhanced. In addition, since the tunnel 115 becomes the closed chamber in the reflective bump 112, the light beams traveling in the interconnection unit 110 can remain in the closed chamber, and thus the effect that preventing the optical signal from leaking out of the package structure 100C can be further enhanced. In addition, the reflective bump 112 of the interconnection unit 110 can prevent other light propagated from the outside of the package structure 100C, such that noise in the optical transmission of the package structure 100C can be reduced.

FIG. 4 is a perspective view of a package structure 100D with the same cross-section as FIG. 1B according to a fourth embodiment of the present disclosure. The difference between the present embodiment and the third embodiment is that the interconnection unit 110 further includes a metal layer 124 disposed in the tunnel 115 of the reflective bump 112 and between the first dielectric layer 118 and the reflective bump 112.

As shown in FIG. 4, similarly to the second embodiment, the tunnel 115 of the reflective bump 112 can be filled with a combination of the first dielectric layer 118 and the metal layer 124, and the metal layer 124 can be made of a material having high reflectivity, such as cooper. Accordingly, the transmission efficiency of the package structure 100D which is referred as the internal transmission can be enhanced. Furthermore, in other embodiments, the first dielectric layer 118 can be omitted, and the reflective bump 112 can be filled with an air gap.

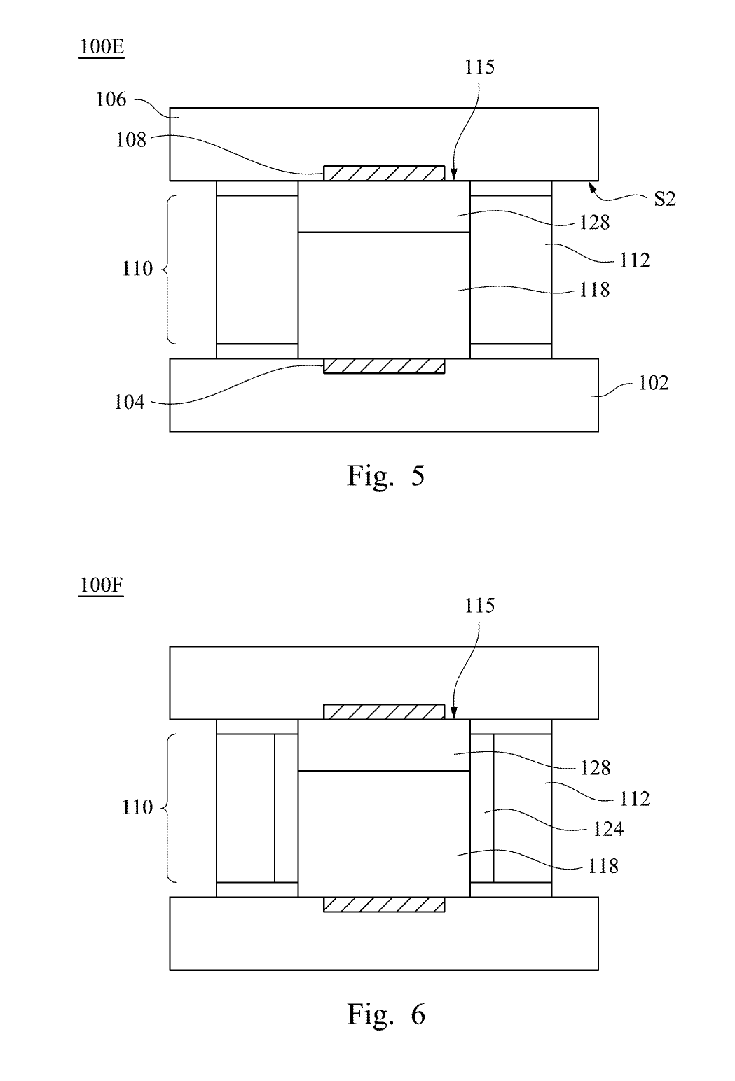

FIG. 5 is a perspective view of a package structure 100E with the same cross-section as FIG. 1B according to a fifth embodiment of the present disclosure. The different between the present embodiment and the third embodiment is that the interconnection unit 110 of the present embodiment further includes a second dielectric layer 128 disposed between the first dielectric layer 118 and the second surface S2 of the second substrate 106.

As shown in FIG. 5, once an air gap (not illustrated) is present between the first dielectric layer 118 and the second substrate 106, total internal reflection of a light beam traveling from the first dielectric layer 118 toward the second optical unit 108 may occur at an interface between the first dielectric layer 118 and the air gap. In this regard, the second dielectric layer 128 can filled in the vacancy between the first dielectric layer 118 and the second substrate 106, and the second dielectric layer 128 can be in contact with the first dielectric layer 118 and the second optical unit 108, but is not limited thereto. Furthermore, the tunnel 115 of the reflective bump 112 can be filled with a combination of the first dielectric layer 118 and the second dielectric layer 128.

The first dielectric layer 118 has a refractive index which is different from that of the second dielectric layer 128, for example, the refractive index of the first dielectric layer 118 may be less than the refractive index of the second dielectric layer 128, and thus the total internal reflection of the light beam traveling from the first dielectric layer 118 toward the second optical unit 108 may be prevented.

FIG. 6 is a perspective view of a package structure 100F with the same cross-section as FIG. 1B according to a sixth embodiment of the present disclosure. The difference between the present embodiment and the fifth embodiment is that the interconnection unit 110 of the present embodiment further includes a metal layer 124 disposed in the tunnel 115 of the reflective bump 112 and between the first dielectric layer 118 and the reflective bump 112.

As shown in FIG. 6, the tunnel 115 of the reflective bump 112 can be filled with a combination of the first dielectric layer 118, the second dielectric layer 128, and the metal layer 124. Similarly to the second and fourth embodiments, the metal layer 124 can be made of a material having high reflectivity, and therefore the transmission efficiency of the package structure 100F which is referred as the internal transmission can be enhanced.

In aforementioned embodiments, the package structure includes the optical unit and the interconnection unit, in which the interconnection unit includes the reflective bump. With the reflective bump, the light beam which does not be propagated toward the optical unit at the start can reach the optical unit through being reflected from the reflective bump. Therefore, the light beam serving as the optical signal can be prevented from leaking out of the package structure, and thus the transmission efficiency of the package structure is enhanced.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the invention. In view of the foregoing, it is intended that the present disclosure cover modifications and variations of the present disclosure provided they fall within the scope of the following claims.

1. A package structure, comprising:
a substrate having a surface;
an interconnection unit disposed on the substrate and comprising:
a reflective bump, wherein the reflective bump is disposed on the surface of the substrate and has an opening therein, and
at least one pad disposed between the substrate and the reflective bump, wherein the pad is in contact with the reflective bump and the surface of the substrate; and
an optical unit joined with the surface of the substrate and configured to receive a light beam from the interconnection unit, wherein a vertical projection of the optical unit on the substrate is present within a vertical projection of the opening of the reflective bump on the substrate.

2. The package structure of claim 1, wherein a vertical projection of the reflective bump on the substrate is closed-loop.

3. The package structure of claim 1, wherein the reflective bump is made of metal.

4. The package structure of claim 1, wherein the interconnection unit further comprises a first dielectric layer disposed in the opening of the reflective bump.

5. The package structure of claim 4, wherein the interconnection unit further comprises:
a second dielectric layer disposed on the first dielectric layer and having a refractive index which is different from that of the first dielectric layer.

6. The package structure of claim 1, wherein the reflective bump has an inner sidewall facing toward the opening, and the interconnection unit further comprises:
a metal layer disposed in the opening of the reflective bump and on the inner sidewall, wherein a vertical projection of the metal layer on the substrate is out of the vertical projection of the optical unit on the substrate.

7. The package structure of claim 6, wherein the vertical projection of the metal layer on the substrate is annular.

8. (canceled)

9. A package structure, comprising:
a first substrate having a first surface;
a second substrate disposed on the first substrate and having a second surface, wherein the first surface and the second surface face toward each other;
an interconnection unit disposed between the first substrate and the second substrate, wherein the interconnection unit comprises:
a reflective bump disposed between the first surface and the second surface and having a tunnel therein, and the tunnel extends from the first surface to the second surface;
at least one first pad disposed between the first substrate and the reflective bump, wherein the first pad is in contact with the reflective bump and the first surface of the first substrate; and
at least one second pad disposed between the second substrate and the reflective bump, wherein the second pad is in contact with the reflective bump and the second surface of the second substrate;
a first optical unit joined with the first surface of the first substrate; and
a second optical unit joined with the second surface of the second substrate, wherein one of the first optical unit and the second optical unit is configured to emit a light beam toward the tunnel and another one of the first optical unit and the second optical unit is configured to receive the light beam from the tunnel.

10. The package structure of claim 9, wherein the reflective bump is made of metal.

11. The package structure of claim 9, wherein the interconnection unit further comprises:
a first dielectric layer disposed in the tunnel of the reflective bump and between the first substrate and the second substrate.

12. The package structure of claim 11, wherein the interconnection unit further comprises:
a second dielectric layer disposed between the first dielectric layer and the second surface and having a refractive index which is different from that of the first dielectric layer.

13. The package structure of claim 9, wherein the reflective bump has an inner sidewall facing toward the opening, and the interconnection unit further comprises:
a metal layer disposed in the tunnel of the reflective bump and on the inner sidewall, wherein a vertical projection of the metal layer on the first substrate is out of a vertical projection of the first optical unit on the first substrate and out of a vertical projection of the second optical unit on the second substrate.

14. The package structure of claim 13, wherein the vertical projection of the metal layer on the first substrate is annular.

15. (canceled)

16. The package structure of claim 9, wherein a vertical projection of the reflective bump on the first substrate is closed-loop.

17. The package structure of claim 16, wherein two ends of the tunnel of the reflective bump are covered with the first substrate and the second substrate, such that the tunnel becomes a closed chamber in the reflective bump.

18. The package structure of claim 17, wherein the interconnection unit further comprises:
a first dielectric layer disposed in the tunnel of the reflective bump and between the first substrate and the second substrate; and
a second dielectric layer disposed between the first dielectric layer and the second surface and having a refractive index which is different from that of the first dielectric layer.

19. The package structure of claim 17, wherein the reflective bump has an inner sidewall facing toward the opening, and the interconnection unit further comprises:
a metal layer disposed in the tunnel of the reflective bump and on the inner sidewall, wherein a vertical projection of the metal layer on the first substrate is out of a vertical projection of the first optical unit on the first substrate and out of a vertical projection of the second optical unit on the second substrate.

20. The package structure of claim 19, wherein the vertical projection of the metal layer on the first substrate is annular.
